(19) United States
(12) Patent Application Publication
(10) Pub. No.: US 2026/0223737 A1
(43) Pub. Date: Jul. 30, 2026

(54) SEMICONDUCTOR PACKAGE AND METHOD FOR FABRICATING THE SAME

(71) Applicant: SAMSUNG ELECTRONICS CO., LTD., Suwon-si (KR)

(72) Inventor: Jinmo Kwon, Suwon-si (KR)

(73) Assignee: SAMSUNG ELECTRONICS CO., LTD., Suwon-si (KR)

(21) Appl. No.: 19/357,634

(22) Filed: Oct. 14, 2025

(30) Foreign Application Priority Data
Jan. 25, 2025 (KR) 10-2025-0009033

(51) Int. Cl. H10W 90/00; H10W 74/10; H10W 72/00; H10W 90/24

(52) U.S. Cl. CPC H10W 90/00; H10W 74/117; H10W 72/884; H10W 90/24; H10W 90/732; H10W 90/754

(57) ABSTRACT

There is provided a semiconductor package including a substrate, a first semiconductor die on the substrate, a second semiconductor die on the first semiconductor die, the second semiconductor die arranged with an offset in a first horizontal direction with respect to the first semiconductor die, a third semiconductor die on the second semiconductor die, the third semiconductor die arranged with an offset in a second horizontal direction opposite to the first horizontal direction with respect to the first semiconductor die, a fourth semiconductor die on the third semiconductor die, the fourth semiconductor die arranged with an offset in the first horizontal direction with respect to the second semiconductor die, and a plurality of bonding wires that electrically connects each of the first semiconductor die, the second semiconductor die, the third semiconductor die, and the fourth semiconductor die to the substrate.

### CROSS-REFERENCE TO RELATED APPLICATION

This application claims priority to and the benefit of Korean Patent Application No. 10-2025-0009033 filed with the Korean Intellectual Property Office on January 21, 2025, the entire contents of which are incorporated herein by reference.

### BACKGROUND

The disclosure relates to a semiconductor package and a method for manufacturing the same.

Recently, electronic products with high-performance and smaller size are desired, and as such, semiconductor packages embedded in electronic products are also becoming smaller with increased performance. In order to manufacture a high-performance semiconductor package, it is necessary to mount as many high-capacity and multi-channel semiconductor dies as possible, and in order to manufacture a miniaturized semiconductor package, it is required to stack thin semiconductor dies with finer wiring patterns and electrically connect the semiconductor dies to each other.

To this purpose, a technology for vertically stacking semiconductor dies is being studied. One method for vertically stacking semiconductor dies is to stack semiconductor dies in a zigzag pattern on a substrate and electrically connect the semiconductor dies to the substrate using bonding wires. A signal from a semiconductor die having a high capacity and multiple channels is transmitted to a substrate via wires through bonding pads located on the upper surface of the semiconductor die.

In a semiconductor package having this structure, the bonding wire connecting the substrate and a semiconductor die located at the top within the semiconductor stack has a longer length than the bonding wire connecting the substrate and a semiconductor die located at the bottom within the semiconductor stack. As the length of the bonding wire increases, the inductance L value increases, so the signal integrity (SI) and power integrity (PI) of the semiconductor die located at the top in the semiconductor stack are bound to deteriorate compared to the signal integrity (SI) and power integrity (PI) of the semiconductor die located at the bottom in the semiconductor stack.

Additionally, a bonding wire having a long length and connected to a semiconductor die located at the top within the semiconductor stack may act as a stub. Bonding wires acting as stubs may physically shake the semiconductor die when it operates at high speed, which causes a reduction in the eye margin and degradation of signal quality.

### SUMMARY

One or more aspect of the disclosure may provide a semiconductor package in which a length of a bonding wire connecting a semiconductor die and a substrate may be reduced.

According to an aspect of the disclosure, there is provided a semiconductor package including: a substrate, a plurality of semiconductor dies stacked on the substrate, the plurality of semiconductor dies including N number of semiconductor dies, wherein N is a natural number greater than or equal to 4, and a plurality of bonding wires, each of the plurality of bonding wires configured to electrically connect one of the plurality of semiconductor dies to the substrate, wherein the plurality of semiconductor dies includes: a first semiconductor die provided on the substrate; a second semiconductor die provided on the first semiconductor die with an offset in a first horizontal direction with respect to the first semiconductor die; an nth semiconductor die provided with an offset in a second horizontal direction opposite to the first horizontal direction with respect to a n-2th semiconductor die, where n is an odd number greater than or equal to 3 and less than or equal to N; and an mth semiconductor die provided with an offset in the first horizontal direction with respect to a m-2th semiconductor die, where m is an even number equal to or greater than 4 and equal to or less than N.

According to an aspect of the disclosure, there is provided a semiconductor package including: a substrate; a first semiconductor die on the substrate; a second semiconductor die on the first semiconductor die, the second semiconductor die arranged with an offset in a first horizontal direction with respect to the first semiconductor die; a third semiconductor die on the second semiconductor die, the third semiconductor die arranged with an offset in a second horizontal direction opposite to the first horizontal direction with respect to the first semiconductor die; a fourth semiconductor die on the third semiconductor die, the fourth semiconductor die arranged with an offset in the first horizontal direction with respect to the second semiconductor die; and a plurality of bonding wires configured to electrically connect each of the first semiconductor die, the second semiconductor die, the third semiconductor die, and the fourth semiconductor die to the substrate.

According to another aspect of the disclosure, there is provided a semiconductor package including: a substrate; a plurality of semiconductor dies stacked on the substrate, the plurality of semiconductor dies including N number of semiconductor dies, wherein N is a natural number greater than or equal to 4, and each of the plurality of semiconductor dies includes a first side and a second side opposite to the first side; and a plurality of bonding wires, each of the plurality of bonding wires configured to electrically connect one of the plurality of semiconductor dies to the substrate, wherein the plurality of semiconductor dies includes: a first semiconductor die provided on the substrate; a second semiconductor die provided on the first semiconductor die such that the first side of the second semiconductor die is recessed based on the first side of the first semiconductor die and the second side of the second semiconductor die protrudes based on the second side of the first semiconductor die, an nth semiconductor die provided such that the first side of the nth semiconductor die protrudes by a first width based on the first side of an n-2th semiconductor die, and the second side of the nth semiconductor die is recessed by the first width based on the second side of the n-2th semiconductor die, wherein n is an odd number equal to or greater than 3 and equal to or less than N, and an mth semiconductor die of the first semiconductor die to the Nth semiconductor die is provided such that the first side of an mth semiconductor die is recessed by a second width based on the first side of the m-2th semiconductor die and the second side of the mth semiconductor die protrudes by the second width based on the second side of the m-2th semiconductor die, and m is an even number equal to or greater than 4 and equal to or less than N.

A semiconductor package according to the disclosure may have a structure in which semiconductor dies are stacked with an offset such that one side of each semiconductor die is close to corresponding substrate pads of a substrate.

Therefore, the length of the bonding wire connected between the semiconductor die located at the top in the semiconductor stack and the corresponding substrate pad may be reduced. Accordingly, the inductance L value in the signal path may be reduced, and the signal integrity (SI) and power integrity (PI) of the semiconductor die located at the top within the semiconductor stack may be improved. In addition, it may prevent the bonding wire from acting as a stub, and improve the eye margin and signal quality of the semiconductor package.

### BRIEF DESCRIPTION OF DRAWINGS

FIG. 1 is a perspective view illustrating a semiconductor package of an embodiment.

FIG. 2 is a cross-sectional view of the semiconductor package of FIG. 1 taken along line A-A.

FIGS. 3A and 3B illustrate an enlarged cross-sectional view of area E of the semiconductor package of FIG. 2.

FIGS. 4A and 4B illustrate an enlarged cross-sectional view of area F of the semiconductor package of FIG. 2.

FIG. 5 is a cross-sectional view of the semiconductor package of FIG. 1 taken along line B-B.

FIG. 6 is a perspective view illustrating a semiconductor package of an embodiment.

FIG. 7 is a cross-sectional view of the semiconductor package of FIG. 1 taken along line A-A.

FIG. 8 is a cross-sectional view of the semiconductor package of FIG. 1 taken along line B-B.

FIGS. 9A-9H are cross-sectional views illustrating a method for manufacturing a semiconductor package according to an embodiment.

### DETAILED DESCRIPTION

Hereinafter, with reference to accompanying drawings, various embodiments of the disclosure will be described in detail so that a person of an ordinary skill can easily implement the disclosure. The disclosure may be implemented in many different forms and is not limited to the embodiments described herein.

In order to clearly explain the disclosure, parts that are not relevant to the description are omitted, and identical or similar components are assigned the same reference numerals throughout the specification.

In addition, the size and thickness of each component shown in the drawings are shown arbitrarily for convenience of explanation, so the disclosure is not necessarily limited to what is shown.

Throughout the specification, when a part is said to be “connected” to another part, this includes not only “directly connected” but also “indirectly connected” through another member. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, being “on” or “above” a reference element means being positioned on or below the reference element, and does not necessarily mean being positioned “above” or “on” in a direction opposite to gravity.

In addition, throughout the specification, when referring to “a plane view”, it means that the target portion is viewed from above, and when referring to “a cross-section view”, it means that a cross section of the target portion cut vertically is viewed from a side.

Hereinafter, a semiconductor package 100, 100A and 100B and a method for manufacturing the semiconductor package 100 according to an embodiment will be described with reference to the drawings.

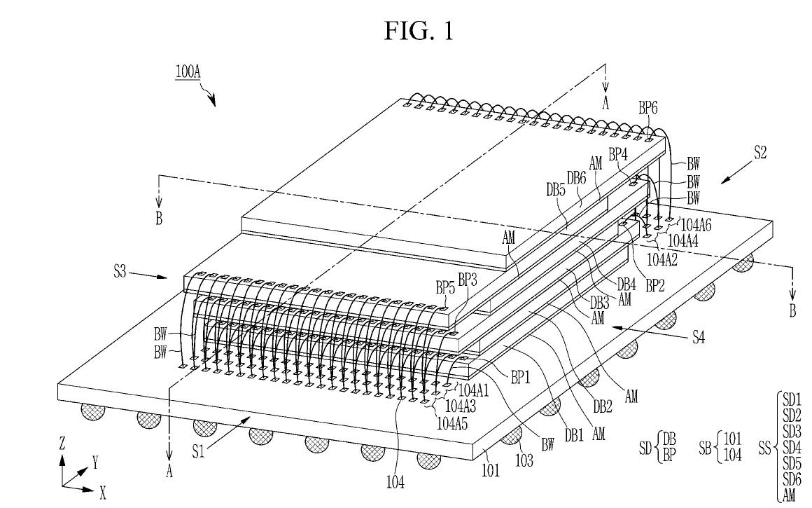

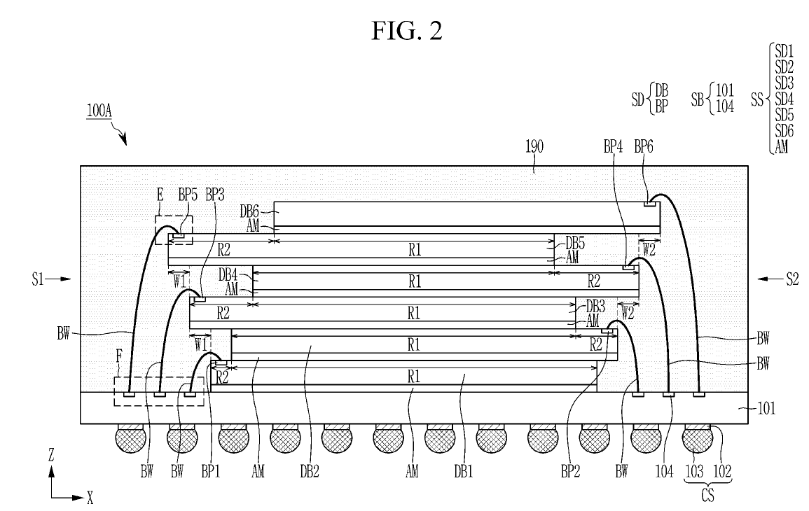

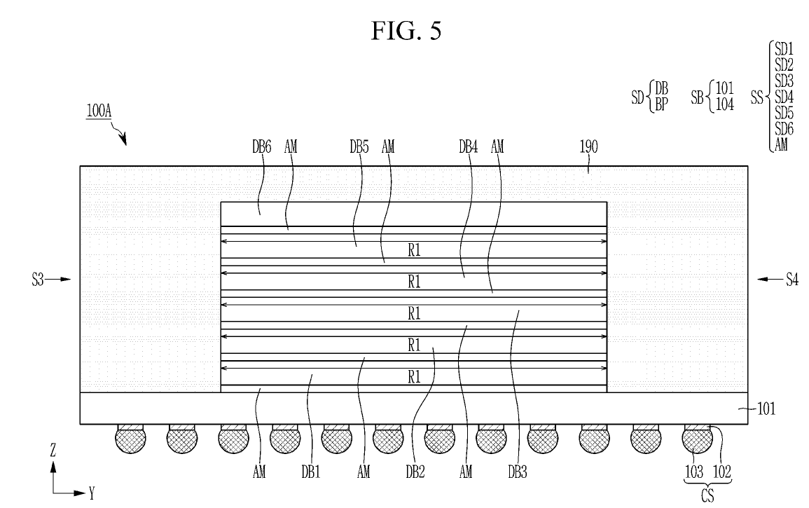

FIG. 1 is a perspective view illustrating a semiconductor package 100A of an embodiment. FIG. 2 is a cross-sectional view of the semiconductor package 100A of FIG. 1 taken along line A-A. FIG. 5 is a cross-sectional view of the semiconductor package 100A of FIG. 1 taken along line B-B. The molding material 190 illustrated in FIGS. 2 and 5 is omitted in FIG. 1.

Referring to FIGS. 1, 2, and 5, a semiconductor package 100A may include a semiconductor stack SS, a substrate SB, an external connection structure CS, a bonding wire BW, and a molding material 190. In an embodiment, the semiconductor package 100A may include a System In Package (SIP). According to an embodiment, the semiconductor package 100A may include two or more semiconductor dies arranged in one semiconductor package and may operate as one chip. In an embodiment, the semiconductor package 100A may be a semiconductor package manufactured based on a Fan Out Wafer Level Package (FOWLP) technology or a Fan Out Panel Level Package (FOPLP) technology. However, the disclosure is not limited thereto, and as such, the semiconductor package may be manufactured in another manner.

According to an embodiment, the semiconductor stack (memory stack) SS may be provided on the substrate SB. The semiconductor stack SS may include a plurality of semiconductor dies (memory dies) SD and a plurality of adhesive members AM. The semiconductor stack SS may include a first semiconductor die SD1 to an Nth semiconductor die SDN. Here, N may be a natural number greater than or equal to 4. The first semiconductor die SD1 to the Nth semiconductor die SDN may be sequentially stacked in a vertical direction (Z direction) on the substrate SB. For example, the first semiconductor die SD1 may be provided on the bottom of the stack and the Nth semiconductor die SDN may be provided on top of the stack. The first semiconductor die SD1 to the Nth semiconductor die SDN may be stacked in a zigzag pattern alternately along a first horizontal direction and a second horizontal direction opposite to the first horizontal direction.

According to an embodiment, the functionality and performance of the semiconductor package 100A may be improved as a greater number of semiconductor dies SD are included in the semiconductor stack SS. However, if a semiconductor stack SS is formed with too many semiconductor dies SD, the length of the bonding wire BW connected to the semiconductor die SD located at the top in the semiconductor stack SS may become excessively long, which may deteriorate the signal integrity SI and power integrity PI of the semiconductor die. In addition, if a semiconductor stack SS is formed with too many semiconductor dies SD, an alignment error occurs between the bonding wire BW and the substrate pads 104, which causes problems such as making it difficult to design the connection between the substrate SB and the semiconductor dies SD according to the stacked structure of the semiconductor dies SD. Therefore, N may be determined by considering the function and performance of the semiconductor package 100A and the connection between the substrate SB and the semiconductor dies SD. Although the drawings according to the disclosure illustrate a semiconductor stack SS having N of 6, the disclosure is not limited thereto, and a semiconductor stack SS including a smaller or larger number of semiconductor dies SD may be included in the disclosure. For example, a semiconductor stack SS may include four to twenty semiconductor dies SD.

The first semiconductor die SD1 to the Nth semiconductor die SDN may each include a die base DB. In an embodiment where N is 6, the first semiconductor die SD1 to the Nth semiconductor die SDN may include a first semiconductor die SD1, a second semiconductor die SD2, a third semiconductor die SD3, a fourth semiconductor die SD4, a fifth semiconductor die SD5 and a sixth semiconductor die SD6. Each of the first semiconductor die SD1 to the sixth semiconductor die SD6 may include the die base DB. For example, the first semiconductor die SD1 may include a first die base DB1, the second semiconductor die SD2 may include a second die base DB2, the third semiconductor die SD3 may include a third die base DB3, the fourth semiconductor die SD4 may include a fourth die base DB4, the fifth semiconductor die SD5 may include a fifth die base DB5 and the sixth semiconductor die SD6 may include a sixth die base DB6. The die base DB may include an active surface facing in a direction opposite to (or away from) the substrate SB. The die base DB may be a die formed from a wafer. In an embodiment, the die base DB may include silicon or other semiconductor material.

Each of the first semiconductor die SD1 to the Nth semiconductor die SDN may include a front side structure on an active surface. The front side structure may include an active layer and a wiring layer. The active layer may be provided on the active surface of the die base. The active layer may include an integrated circuit structure having integrated circuit regions. In an embodiment, the integrated circuit structure may include at least one of an active device and a passive device. In an embodiment, an integrated circuit structure may include a gate structure, a source region, and a drain region. In an embodiment, the integrated circuit structure may include at least one of a transistor, a diode, a capacitor, an inductor, and a resistor. The wiring layer may be provided on the active layer. The wiring layer may include, but is not limited to, signal wiring lines, power wiring lines, contact plugs, and intermetal dielectric IMD. In an embodiment, the semiconductor die may include, but is not limited to, a volatile or non-volatile memory die.

The first semiconductor die SD1 to the Nth semiconductor die SDN may each include a first side S1, a second side S2 opposite the first side S1, a third side S3 between the first side S1 and the second side S2, and a fourth side S4 opposite the third side S3. The first side S1 and the second side S2 may extend in the Y direction (the third horizontal direction) or in the -Y direction (the fourth horizontal direction) which is opposite to the Y direction (the third horizontal direction). The third side S3 and the fourth side S4 may extend in the X direction (the fifth horizontal direction) intersecting the Y direction (the third horizontal direction) or in the -X direction (the sixth horizontal direction) which is opposite to the X direction (the fifth horizontal direction).

Each of the first semiconductor die SD1 to the Nth semiconductor die SDN may include bonding pads BP provided on an active surface of a die base DB. The bonding pads BP included in each of the first semiconductor die SD1 to the Nth semiconductor die SDN may be defined as the first bonding pads BP1 to the Nth bonding pads BPN. In an embodiment where N is 6, each of the first semiconductor die SD1 to the sixth semiconductor die SD6 may include each of the first bonding pads BP1 to the sixth bonding pads BP6. The bonding pads BP may form bonding pad arrays on corresponding semiconductor die among the first semiconductor die SD1 to the Nth semiconductor die SDN. For example, the bonding pads BP may include first bonding pad arrays BP1, second bonding pad arrays BP2, third bonding pad arrays BP3, fourth bonding pad arrays BP4, fifth bonding pad arrays BP5, and sixth bonding pad arrays BP6. Each of the bonding pad arrays may be arranged conformally and in a row on an area of an upper surface of each of the first semiconductor die SD1 to the Nth semiconductor die SDN that is not covered by a neighboring semiconductor die. Each of the bonding pads BP may be electrically and physically connected to a corresponding bonding wire BW among the bonding wires BW, and may be electrically connected to the substrate SB through the corresponding bonding wire BW among the bonding wires BW. In an embodiment, the bonding pads BP may include, but is not limited to, at least one of copper, nickel, zinc, gold, silver, platinum, palladium, chromium, titanium and alloys thereof.

In an embodiment where N may be 6, the first bonding pad arrays BP1 may be arranged conformally and in a row along the first side S1 of the first semiconductor die SD1 on a second region R2 of the upper surface of the first semiconductor die SD1 that is not covered by the second semiconductor die SD2. The second bonding pad arrays BP2 may be arranged conformally and in a row along the second side S2 of the second semiconductor die SD2 on a second region R2 of the upper surface of the second semiconductor die SD2 that is not covered by the third semiconductor die SD3. The third bonding pad arrays BP3 may be arranged conformally and in a row along the first side S1 of the third semiconductor die SD3 on a second region R2 of the upper surface of the third semiconductor die SD3 that is not covered by the fourth semiconductor die SD4. The fourth bonding pad arrays (BP4) may be arranged conformally and in a row along the second side S2 of the fourth semiconductor die SD4 on a second region R2 of the upper surface of the fourth semiconductor die SD4 that is not covered by the fifth semiconductor die SD5. The fifth bonding pad arrays BP5 may be arranged conformally and in a row along the first side S1 of the fifth semiconductor die SD5 on a second region R2 of the upper surface of the fifth semiconductor die SD5 that is not covered by the sixth semiconductor die SD6. The sixth bonding pad arrays BP6 may be arranged conformally and in a row along the second side S2 of the sixth semiconductor die SD6 on the upper surface of the sixth semiconductor die SD6.

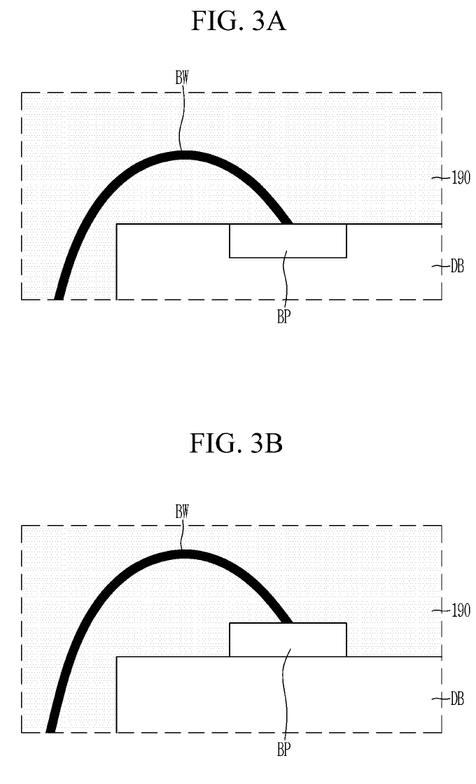

An embodiment of the arrangement of bonding pads BP is illustrated in FIGS. 3A and 3B. For example, FIGS. 3A and 3B illustrate an enlarged cross-sectional view of area E of the semiconductor package of FIG. 2. For example, area E of FIG. 2 illustrates fifth bonding pads BP5 on a fifth base die BD5, but the disclosure is not limited thereto, and as such, an embodiment of FIG. 3 may also be applied to bonding pads BP on other base dies BD.

Referring to FIG. 3A, the side surfaces and the lower surfaces of each of the bonding pads BP may be surrounded and embedded by the die base DB. The upper surface of each of the bonding pads BP may exposed from the die base DB and may be connected to a bonding wire BW. Referring to FIG. 3B, the bonding pads BP may protrude from the die base DB. The upper surface and side surfaces of each of the bonding pads BP may be exposed from the die base DB and surrounded by a molding material 190, and the upper surface of each of the bonding pads BP may be connected to a bonding wire BW. The lower surface of each of the bonding pads BP may contact the die base DB.

Referring to FIG. 2, the first semiconductor die SD1 may be provided on the substrate SB, and the second semiconductor die SD2 may be provided with an offset in a first horizontal direction from the first semiconductor die SD1. The first horizontal direction may be the same direction as the X direction (the fifth horizontal direction). The first side S1 of the second semiconductor die SD2 may be recessed based on the first side S1 of the first semiconductor die SD1. The second side S2 of the second semiconductor die SD2 may protrude based on the second side S2 of the first semiconductor die SD1.

The nth semiconductor die SDn among the first semiconductor die SD1 to the Nth semiconductor die SDN may be provided with an offset in the second horizontal direction that is opposite to the first horizontal direction from the n-2th semiconductor die SDn-2. The second horizontal direction may be in the same direction as the -X direction (the sixth horizontal direction). For example, n may be an odd number greater than or equal to 3 and less than or equal to N. A first side S1 of the nth semiconductor die SDn may protrude by a first width W1 based on the first side S1 of the n-2th semiconductor die SDn-2. The second side S2 of the nth semiconductor die SDn may be recessed by a first width W1 based on the second side S2 of the n-2th semiconductor die SDn-2. In an embodiment, the first width W1 may have a range of about 50 μm to about 100 μm.

The mth semiconductor die SDm among the first semiconductor die SD1 to the Nth semiconductor die SDN may be provided with an offset in the first horizontal direction from the m-2th semiconductor die SDm-2. For example, m may be an even number greater than or equal to 4 and less than or equal to N. A first side S1 of the m semiconductor die SDm may be recessed by a second width W2 based on the first side S1 of the m-2 semiconductor die SDm-2.

The second side S2 of the m semiconductor die SDm may protrude by the second width W2 based on the second side S2 of the m-2 semiconductor die SDm-2. In an embodiment, the second width W2 may have a range of about 50 μm to about 100 μm.

According to an embodiment, the upper surface of each of the first semiconductor die SD1 to the N-1th semiconductor die SDN-1 may include a first region R1 overlapping a neighboring (or adjacent) semiconductor die and a second region R2 not overlapped by the neighboring (or adjacent) semiconductor die. For example, the upper surface of each of the first semiconductor die SD1 to the N-1th semiconductor die SDN-1 may include a first region R1 covered by a neighboring semiconductor die and a second region R2 exposed from the neighboring semiconductor die.

The Nth semiconductor die SDN may not be covered by another semiconductor die. The area of the second region R2 may increase from the first semiconductor die SD1 to the N-1 semiconductor die SDN-1.

In an embodiment where N is 6, the third semiconductor die SD3 may be provided with an offset in the second horizontal direction from the first semiconductor die SD1. The first side S1 of the third semiconductor die SD3 may protrude by a first width W1 based on the first side S1 of the first semiconductor die SD1. The second side S2 of the third semiconductor die SD3 may be recessed by the first width W1 based on the second side S2 of the first semiconductor die SD1. The fourth semiconductor die SD4 may be provided with an offset in the first horizontal direction from the second semiconductor die SD2. The first side S1 of the fourth semiconductor die SD4 may be recessed by a second width W2 based on the first side S1 of the second semiconductor die SD2. The second side S2 of the fourth semiconductor die SD4 may protrude by the second width W2 based on the second side S2 of the second semiconductor die SD2. The fifth semiconductor die SD5 may be provided with an offset in the second horizontal direction from the third semiconductor die SD3. The first side S1 of the fifth semiconductor die SD5 may protrude by a first width W1 based on the first side S1 of the third semiconductor die SD3. The second side S2 of the fifth semiconductor die SD5 may be recessed by a first width W1 based on the second side S2 of the third semiconductor die SD3. The sixth semiconductor die SD6 may be provided with an offset in the first horizontal direction from the fourth semiconductor die SD4. The first side S1 of the sixth semiconductor die SD6 may be recessed by the second width W2 based on the first side S1 of the fourth semiconductor die SD4. The second side S2 of the sixth semiconductor die SD6 may protrude by the second width W2 based on the second side S2 of the fourth semiconductor die SD4. The area of second region R2 of each of the first semiconductor die SD1 to the fifth semiconductor die SD5 may increase as it goes from the first semiconductor die SD1 to the fifth semiconductor die SD5.

Referring to FIG. 5, the third side S3 and the fourth side S4 of each of the first semiconductor die SD1 to the Nth semiconductor die SDN may be stacked while being aligned with each other without being offset from each other and without being protruded or recessed.

Referring again to FIGS. 1, 2, and 5, the adhesive members AM may be alternately stacked with the semiconductor dies SD. In an embodiment, the adhesive members AM may include, but is not limited to, a die attach film (DAF).

According to an embodiment, the substrate SB may include a substrate base 101 and substrate pads (104). In an embodiment, the substrate SB may include, but is not limited to, an Ajinomoto Build-up Film (ABF) substrate. In an embodiment, the substrate SB may include a printed circuit board. According to an embodiment, the substrate SB may be replaced by a silicon interposer, a redistribution interposer, a composite interposer, a redistribution structure, or a wafer-level semiconductor die. For example, a silicon interposer, a redistribution interposer, a composite interposer, a redistribution structure, or a wafer-level semiconductor die may be stacked with the semiconductor dies SD.

The substrate base 101 may include an insulating layer and wiring layers and vias within the insulating layer. The substrate pads 104 may be provided on the substrate base 101. The substrate pads 104 may be provided next to the first side S1 of the first semiconductor die SD1 and next to the second side S2 of the first semiconductor die SD1.

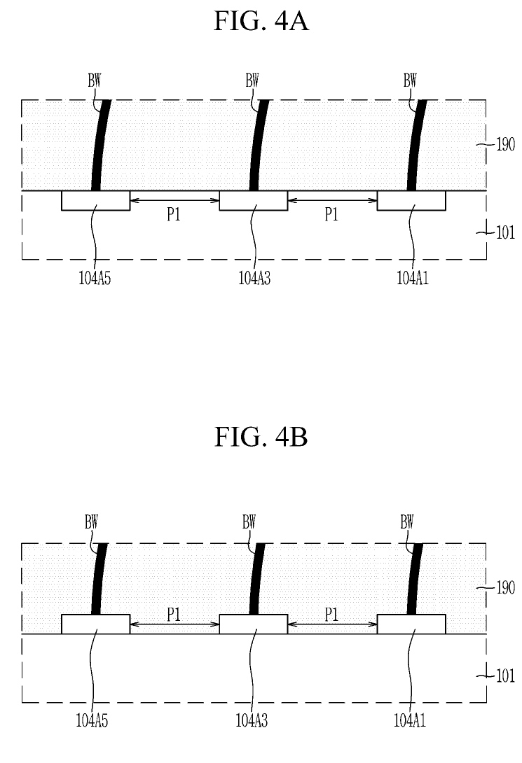

The substrate pads 104 may form substrate pad arrays next to the first side S1 and next to the second side S2 of the first semiconductor die SD1. The substrate pad arrays may include a first substrate pad array 104A1, a second substrate pad array 104A2, a third substrate pad array 104A3, a fourth substrate pad array 104A4, a fifth substrate pad array 104A5, and a sixth substrate pad array 104A6. The first substrate pad array 104A1 among the substrate pad arrays may be arranged conformally and in a row along the first side S1 of the first semiconductor die SD1. The second substrate pad array 104A2 among the substrate pad arrays may be arranged conformally and in a row along the second side S2 of the second semiconductor die SD1. The nth substrate pad array 104An among the substrate pad arrays may be arranged conformally and in a row along the first side S1 of the nth semiconductor die SDn, and spaced apart from the n-2th substrate pad array 104An-2 by a first pitch P1 (see FIGS. 4A and 4B). The mth substrate pad array 104Am among the substrate pad arrays may be arranged conformally and in a row along the second side S2 of the mth semiconductor die SDm and spaced apart from the m-2th substrate pad array 104Am-2 by a first pitch P1 (see FIGS. 4A and 4B).

In an embodiment where N is 6, the third substrate pad array 104A3 may be arranged conformally and in a row along the first side S1 of the third semiconductor die SD3 and spaced apart from the first substrate pad array 104A1 by a first pitch P1. The fourth substrate pad array 104A4 may be arranged conformally and in a row along the second side S2 of the fourth semiconductor die SD4, and spaced apart from the second substrate pad array 104A2 by a first pitch P1. The fifth substrate pad array 104A5 may be arranged conformally and in a row along the first side S1 of the fifth semiconductor die SD5, and spaced apart from the third substrate pad array 104A3 by a first pitch P1. The sixth substrate pad array 104A6 may be arranged conformally and in a row along the second side S2 of the sixth semiconductor die SD6, and spaced apart from the fourth substrate pad array 104A4 by a first pitch P1.

Each of the substrate pads 104 may be electrically and physically connected to a corresponding bonding wire BW among the bonding wires BW, and may be electrically connected to a corresponding bonding pad BP among the bonding pads BP through a corresponding bonding wire BW among the bonding wires BW. In an embodiment, the substrate pads 104 may include, but is not limited to, at least one of copper, nickel, zinc, gold, silver, platinum, palladium, chromium, titanium, and alloys thereof.

An embodiment of the arrangement of substrate pads (104) is illustrated in FIGS. 4A and 4B.

FIGS. 4A and 4B illustrate an enlarged cross-sectional view of area F of the semiconductor package of FIG. 2.

Referring to FIG. 4A, the side surfaces and the lower surface of each of the substrate pads (104) may be surrounded and embedded by the substrate base 101. The upper surface of each of the substrate pads 104 may be exposed from the substrate base 101 and connected to the bonding wire BW. Neighboring substrate pad arrays (104A) among the substrate pad arrays (104A) may be spaced apart from each other by a first pitch (P1). In an embodiment, the first pitch (P1) may have a range of about 100 μm to about 200 μm. Referring to FIG. 4B, the substrate pads 104 may protrude from the substrate base 101. The upper surface and side surfaces of each of the substrate pads 104 may be exposed from the die base DB and surrounded by a molding material 190, and the upper surface of each of the substrate pads 104 may be connected to the bonding wire BW. The lower surface of each of the substrate pads 104 may contact the substrate base 101. Neighboring substrate pad arrays 104A among the substrate pad arrays 104A may be spaced apart from each other by a first pitch P1. In an embodiment, the first pitch P1 may have a range of about 100 μm to about 200 μm.

Referring again to FIGS. 1, 2, and 5, the external connection structure CS may be provided on the lower surface of the substrate base 101. The external connection structure CS may include conductive pads 102 and solders 103. Each of the conductive pads 102 may electrically connect a corresponding wire among the wires in the substrate base 101 to a corresponding solder 103 among the solders 103. The external connection structure CS may electrically connect a semiconductor package 100A to an external device.

Each of the bonding wires BW may electrically connect a corresponding semiconductor die SD among the first semiconductor die SD1 to the Nth semiconductor die SDN to the substrate SB. Each of the bonding wires BW may electrically connect a corresponding substrate pad 104 among the substrate pads 104 to a corresponding bonding pad BP among the bonding pads BP. A first end of each of the bonding wires BW may be electrically connected to a corresponding bonding pad BP among the bonding pads BP. A second end, which is opposite to first end of each of the bonding wires BW may be electrically connected to a corresponding substrate pad 104 among the substrate pads 104. In an embodiment, the bonding wires BW may include at least one of gold, silver, copper, lead, platinum, and alloys thereof.

According to the disclosure, the nth semiconductor die SDn may be provided with an offset in the second horizontal direction opposite to the first horizontal direction from the n-2th semiconductor die (SDn-2), and the mth semiconductor die SDm may be provided with an offset in the first horizontal direction from the m-2th semiconductor die SDm-2. Accordingly, the distance between the corresponding nth bonding pad BPn among the nth bonding pads BPn on the nth semiconductor die SDn connected to each of the bonding wire BW and the corresponding substrate pad 104 in the nth substrate pad array 104An on the substrate SB is shortened, and the length of the bonding wire (BW) connecting the corresponding nth bonding pad BPn among the nth bonding pads BPn on the nth semiconductor die SDn to the corresponding substrate pad 104 in the nth substrate pad array 104An on the substrate (SB) is reduced. Accordingly, the inductance L value in the signal path may be reduced, and the signal integrity SI and power integrity PI of the semiconductor die SD located at the top within the semiconductor stack SS may be improved. In addition, it is possible to prevent bonding wires BW from acting as stubs, and improve the eye margin and signal quality of the semiconductor package 100A.

The molding material 190 may cover the semiconductor stack SS and bonding wires BW on the substrate SB. The molding material 190 protects the semiconductor stack SS and bonding wires BW from the external environment, thereby ensuring the electrical and mechanical stability of the semiconductor package 100A.

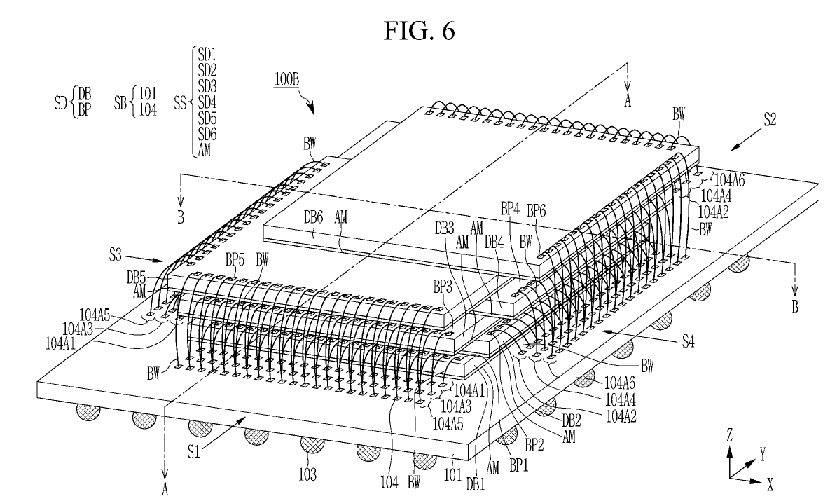

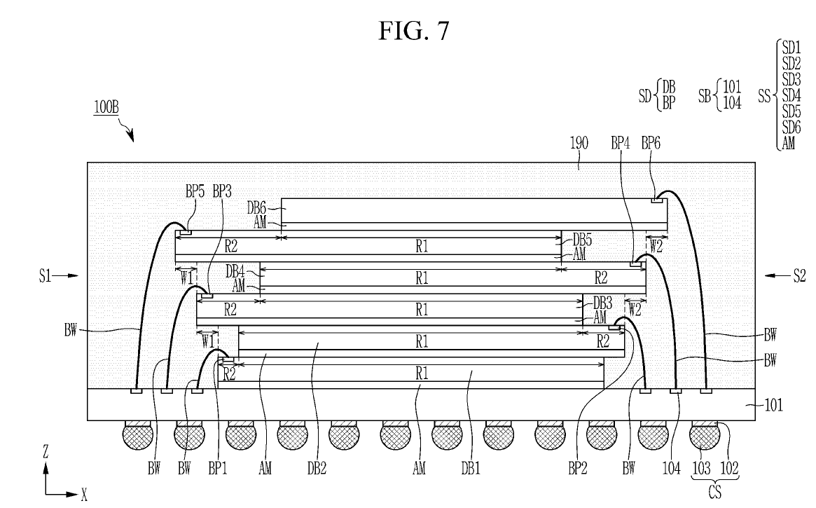

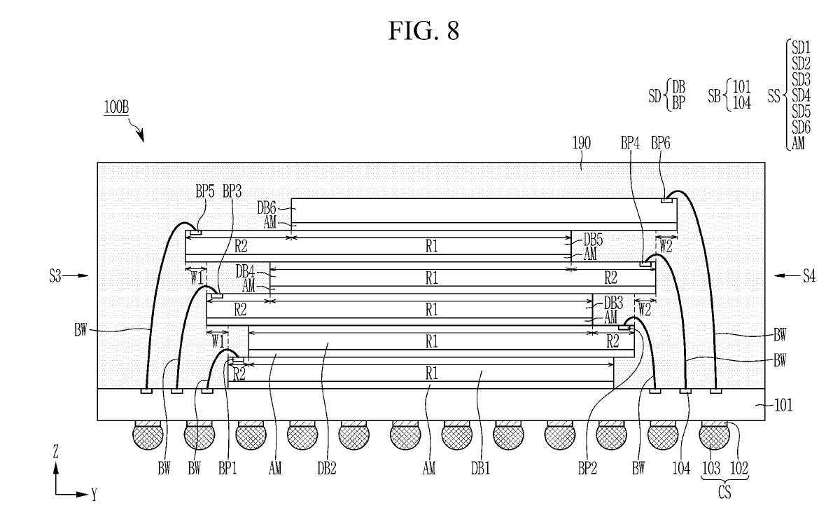

FIG. 6 is a perspective view illustrating a semiconductor package 100B of an embodiment. FIG. 7 is a cross-sectional view of the semiconductor package 100B of FIG. 1 taken along line A-A. FIG. 8 is a cross-sectional view of the semiconductor package 100B of FIG. 1 taken along line B-B. The illustration of the molding material 190 illustrated in FIGS. 7 and 8 is omitted in FIG. 6.

Referring to FIGS. 6, 7, and 8, the first semiconductor die SD1 to the Nth semiconductor die SDN may be alternately stacked in a zigzag pattern along the first horizontal direction and the second horizontal direction opposite to the first horizontal direction.

A first semiconductor die SD1 may be provided on a substrate SB, and a second semiconductor die SD2 may be provided with an offset in the first horizontal direction from the first semiconductor die SD1. The first horizontal direction may be a direction between the X direction (the fifth horizontal direction) and the Y direction (the third horizontal direction). The first side S1 of the second semiconductor die SD2 may be recessed based on the first side S1 of the first semiconductor die SD1.

The third side S3 of the second semiconductor die SD2 may be recessed based on the third side S3 of the first semiconductor die SD1.

The second side S2 of the second semiconductor die SD2 may protrude based on the second side S2 of the first semiconductor die SD1.

The fourth side S4 of the second semiconductor die SD2 may protrude based on the fourth side S4 of the first semiconductor die SD1.

The nth semiconductor die SDn among the first semiconductor die SD1 to the Nth semiconductor die SDN may be provided with an offset in the second horizontal direction that is opposite to the first horizontal direction from the n-2th semiconductor die SDn-2. The second horizontal direction may be a direction between the -X direction (sixth horizontal direction) and the -Y direction (fourth horizontal direction). n may be an odd number greater than or equal to 3 and less than or equal to N. A first side S1 of the nth semiconductor die SDn may protrude by a first width W1 based on the first side S1 of the n-2th semiconductor die SDn-2. The third side S3 of the nth semiconductor die SDn may protrude by a first width W1 based on the third side S3 of the n-2th semiconductor die SDn-2. The second side S2 of the nth semiconductor die SDn may be recessed by a first width W1 based on the second side S2 of the n-2th semiconductor die SDn-2. The fourth side S4 of the nth semiconductor die SDn may be recessed by a first width W1 based on the fourth side S4 of the n-2th semiconductor die SDn-2. In an embodiment, the first width W1 may have a range of about 50 μm to about 100 μm.

The mth semiconductor die SDm among the first semiconductor die SD1 to the Nth semiconductor die SDN may be provided with an offset in the first horizontal direction from the m-2th semiconductor die SDm-2. m may be an even number greater than or equal to 4 and less than or equal to N. A first side S1 of the mth semiconductor die SDm may be recessed by a second width W2 based on the first side S1 of the m-2th semiconductor die SDm-2. The third side S3 of the mth semiconductor die SDm may be recessed by a second width W2 based on the third side S3 of the m-2th semiconductor die SDm-2. The second side S2 of the mth semiconductor die SDm may protrude by a second width W2 based on the second side S2 of the m-2th semiconductor die SDm-2. The fourth side S4 of the mth semiconductor die SDm may protrude by a second width W2 based on the fourth side S4 of the m-2th semiconductor die SDm-2. In an embodiment, the second width W2 may have a range of about 50 μm to about 100 μm.

According to an embodiment, the upper surface of each of the first semiconductor die SD1 to the N-1th semiconductor die SDN-1 may include a first region R1 overlapping a neighboring (or adjacent) semiconductor die and a second region R2 not overlapped by the neighboring (or adjacent) semiconductor die. For example, the upper surface of each of the first semiconductor die SD1 to the N-1th semiconductor die SDN-1 may include a first region R1 covered by a neighboring semiconductor die and a second region R2 exposed from the neighboring semiconductor die. The Nth semiconductor die SDN may not be covered by another semiconductor die. The area of the second region R2 may increase from the first semiconductor die SD1 to the N-1th semiconductor die SDN-1.

In an embodiment where N is 6, the third semiconductor die SD3 may be provided with an offset in the second horizontal direction from the first semiconductor die SD1. The first side S1 of the third semiconductor die SD3 may protrude by a first width W1 based on the first side S1 of the first semiconductor die SD1. The third side S3 of the third semiconductor die SD3 may protrude by a first width W1 based on the third side S3 of the first semiconductor die SD1. The second side S2 of the third semiconductor die SD3 may be recessed by a first width W1 based on the second side S2 of the first semiconductor die SD1. The fourth side S4 of the third semiconductor die SD3 may be recessed by a first width W1 based on the fourth side S4 of the first semiconductor die SD1. The fourth semiconductor die SD4 may be provided with an offset in the first horizontal direction from the second semiconductor die SD2. The first side S1 of the fourth semiconductor die SD4 may be recessed by a second width W2 based on the first side S1 of the second semiconductor die SD2. The third side S3 of the fourth semiconductor die SD4 may be recessed by a second width W2 based on the third side S3 of the second semiconductor die SD2. The second side S2 of the fourth semiconductor die SD4 may protrude by a second width W2 based on the second side S2 of the second semiconductor die SD2. The fourth side S4 of the fourth semiconductor die SD4 may protrude by a second width W2 based on the fourth side S4 of the second semiconductor die SD2. The fifth semiconductor die SD5 may be provided with an offset in the second horizontal direction from the third semiconductor die SD3. The first side S1 of the fifth semiconductor die SD5 may protrude by a first width W1 based on the first side S1 of the third semiconductor die SD3. The third side S3 of the fifth semiconductor die SD5 may protrude by a first width W1 based on the third side S3 of the third semiconductor die SD3. The second side S2 of the fifth semiconductor die SD5 may be recessed by a first width W1 based on the second side S2 of the third semiconductor die SD3. The fourth side S4 of the fifth semiconductor die SD5 may be recessed by a first width W1 based on the fourth side S4 of the third semiconductor die SD3. The sixth semiconductor die SD6 may be provided with an offset in the first horizontal direction from the fourth semiconductor die SD4. The first side S1 of the sixth semiconductor die SD6 may be recessed by a second width W2 based on the first side S1 of the fourth semiconductor die SD4. The third side S3 of the sixth semiconductor die SD6 may be recessed by a second width W2 based on the third side S3 of the fourth semiconductor die SD4. The second side S2 of the sixth semiconductor die SD6 may protrude by a second width W2 based on the second side S2 of the fourth semiconductor die SD4. The fourth side S4 of the sixth semiconductor die SD6 may protrude by a second width W2 based on the fourth side S4 of the fourth semiconductor die SD4. The area of the second region R2 of each of the first semiconductor die SD1 to the fifth semiconductor die SD5 may increase as it goes from the first semiconductor die SD1 to the fifth semiconductor die SD5.

Each of the first semiconductor die SD1 to the Nth semiconductor die SDN may include bonding pads BP provided on an active surface of the die base SB. The bonding pads BP included in each of the first semiconductor die SD1 to the Nth semiconductor die SDN may be defined as the first bonding pads BP1 to the Nth bonding pads BPN. In an embodiment where N is 6, each of the first semiconductor die SD1 to the sixth semiconductor die SD6 may include each of the first bonding pads BP1 to the sixth bonding pads BP6. The bonding pads BP may form bonding pad arrays on corresponding semiconductor die among the first semiconductor die SD1 to the Nth semiconductor die SDN. Each of the bonding pad arrays may be arranged conformally and in a row on an area of an upper surface of each of the first semiconductor die SD1 to the Nth semiconductor die SDN that is not covered by a neighboring semiconductor die.

In an embodiment where N is 6, the first bonding pad arrays BP1 may be arranged conformally and in a row along the first side S1 and the third side S3 of the first semiconductor die SD1 on the second region R2 of the upper surface of the first semiconductor die SD1 that is not covered by the second semiconductor die SD2. The second bonding pad arrays BP2 may be arranged conformally and in a row along the second side S2 and the fourth side S4 of the second semiconductor die SD2 on the second region R2 of the upper surface of the second semiconductor die SD2 that is not covered by the third semiconductor die SD3. The third bonding pad arrays BP3 may be arranged conformally and in a row along the first side S1 and the third side S3 of the third semiconductor die SD3 on the second region R2 of the upper surface of the third semiconductor die SD3 that is not covered by the fourth semiconductor die SD4. The fourth bonding pad arrays BP4 may be arranged conformally and in a row along the second side S2 and the fourth side S4 of the fourth semiconductor die SD4 on the second region R2 of the upper surface of the fourth semiconductor die SD4 that is not covered by the fifth semiconductor die SD5. The fifth bonding pad arrays BP5 may be arranged conformally and in a row along the first side S1 and the third side S3 of the fifth semiconductor die SD5 on the second region R2 of the upper surface of the fifth semiconductor die SD5 that is not covered by the sixth semiconductor die SD6. The sixth bonding pad arrays BP6 may be arranged conformally and in a row along the second side S2 and the fourth side S4 of the sixth semiconductor die SD6 on the upper surface of the sixth semiconductor die SD6.

The substrate SB may include a substrate base 101 and substrate pads 104. The substrate pads 104 may be provided on the substrate base 101. Substrate pads 104 may be provided around the first semiconductor die SD1. The substrate pads 104 may be provided next to the first side S1, the second side S2, the third side S3, and the fourth side S4 of the first semiconductor die SD1.

The substrate pads 104 may form substrate pad arrays around the first semiconductor die SD1. The first substrate pad array 104A1 among the substrate pad arrays may be arranged conformally and in a row along the first side S1 and the third side S3 of the first semiconductor die SD1. The second substrate pad array 104A2 among the substrate pad arrays may be arranged conformally and in a row along the second side S2 and the fourth side S4 of the second semiconductor die SD1. The nth substrate pad array 104An among the substrate pad arrays may be arranged conformally and in a row along the first side S1 and the third side S3 of the nth semiconductor die SDn, and spaced apart from the n-2th substrate pad array 104An-2 by a first pitch P1 (see FIGS. 4A and 4B). The mth substrate pad array 104Am among the substrate pad arrays may be arranged conformally and in a row along the second side S2 and the fourth side S4 of the mth semiconductor die SDm, and spaced apart from the m-2th substrate pad array 104Am-2 by a first pitch P1 (see FIGS. 4A and 4B).

In an embodiment where N is 6, the third substrate pad array 104A3 may be arranged conformally and in a row along the first side S1 and the third side S3 of the third semiconductor die SD3, and spaced apart from the first substrate pad array 104A1 by a first pitch P1. The fourth substrate pad array 104A4 may be arranged conformally and in a row along the second side S2 and the fourth side S4 of the fourth semiconductor die SD4, and spaced apart from the third substrate pad array 104A3 by a first pitch P1. The fifth substrate pad array 104A5 may be arranged conformally and in a row along the first side S1 and the third side S3 of the fifth semiconductor die SD5, and spaced apart from the third substrate pad array 104A3 by a first pitch P1. The sixth substrate pad array 104A6 may be arranged conformally and in a row along the second side S2 and the fourth side S4 of the sixth semiconductor die SD6, and spaced apart from the fourth substrate pad array 104A4 by a first pitch P1.

The contents described for the semiconductor package 100A in FIGS. 1 to 5 may be applied for contents other than those described for the semiconductor package 100B of an embodiment in FIGS. 6, 7, and 8.

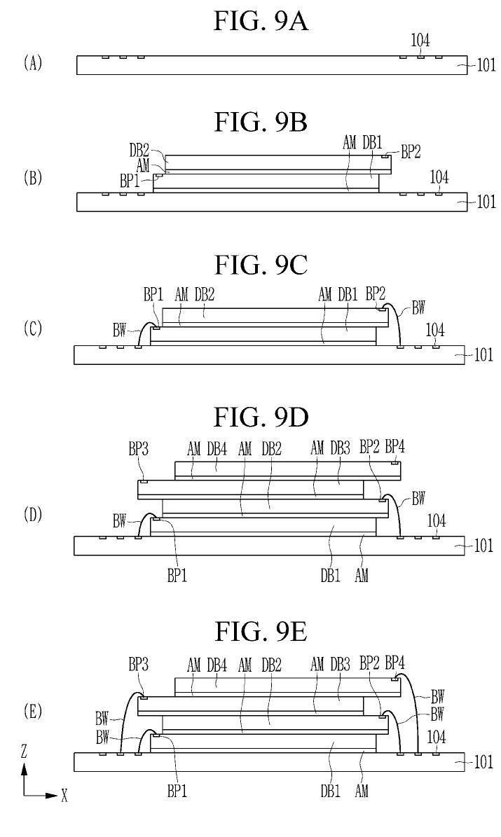

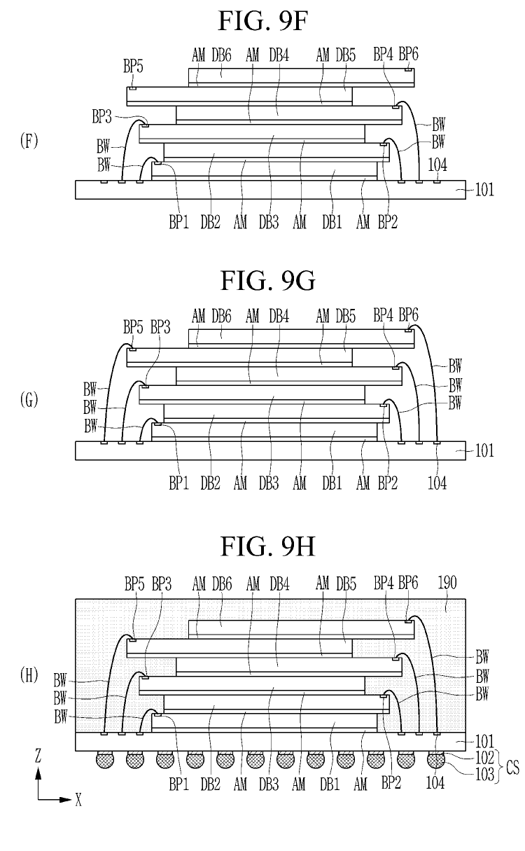

FIGS. 9A to 9H are cross-sectional views illustrating a method for manufacturing a semiconductor package 100 of an embodiment.

Referring to FIG. 9A, according to an embodiment. the method may include an operation (A), in which, a substrate SB may be provided.

Referring to FIG. 9B, according to an embodiment, the method may include an operation (B), in which, a first semiconductor die SD1 may be stacked on a substrate SB using an adhesive member AM, and a second semiconductor die SD1 may be stacked on the first semiconductor die SD1 using the adhesive member AM. The second semiconductor die SD2 may be stacked with an offset in a first horizontal direction from the first semiconductor die SD1 such that first bonding pads BP1 on the first semiconductor die SD1 are exposed.

Referring to FIG. 9C, according to an embodiment, the method may include an operation (C), in which, a capillary may be aligned on the substrate pad 104 and one end of the wire may be made into a ball shape using the capillary. The ball may be formed by applying heat to the tip of the capillary, or by applying a spark to one end of the wire. According to an embodiment, after the ball is formed, the ball may be thermo-pressed onto the substrate pad 104 using the capillary. Next, the wire pressed to the substrate pad 104 may be stretched to raise the capillary by a predetermined distance, and the other end of the wire may be pressed to the bonding pad BP. Next, the wire may be cut. By repeating these processes, bonding wires BW connecting the first bonding pads BP2 on the first semiconductor die SD1 to the substrate pads 104 may be formed, and bonding wires BW connecting the second bonding pads BP2 on the second semiconductor die SD2 to the substrate pads 104 may be formed.

Referring to FIG. 9D, according to an embodiment, the method may include an operation (D), in which, a third semiconductor die SD3 may be stacked on the second semiconductor die SD2 using an adhesive member AM, and a fourth semiconductor die SD4 may be stacked on the third semiconductor die SD3 using an adhesive member AM. The third semiconductor die SD3 may be stacked with an offset in the second horizontal direction from the first semiconductor die SD1. The fourth semiconductor die SD4 may be stacked with an offset in the first horizontal direction from the second semiconductor die SD2.

Referring to FIG. 9E, according to an embodiment, the method may include an operation (E), in which, by repeating the bonding wire forming process of operation (C), bonding wires BW connecting third bonding pads BP3 on a third semiconductor die SD3 to substrate pads 104 may be formed, and bonding wires BW connecting fourth bonding pads BP4 on a fourth semiconductor die SD4 to substrate pads 104 may be formed.

Referring to FIG. 9F, according to an embodiment, the method may include an operation (F), in which, a fifth semiconductor die SD5 may be stacked on a fourth semiconductor die SD4 using an adhesive member AM, and a sixth semiconductor die SD6 may be stacked on the fifth semiconductor die SD5 using the adhesive member AM. The fifth semiconductor die SD5 may be stacked with an offset in the second horizontal direction from the third semiconductor die SD3. The sixth semiconductor die SD6 may be stacked with an offset in the first horizontal direction from the fourth semiconductor die SD4.

Referring to FIG. 9G, according to an embodiment, the method may include an operation (G), in which, by repeating the bonding wire forming process of operation (C), bonding wires BW connecting the fifth bonding pads BP5 on the fifth semiconductor die SD5 to the substrate pads 104 may be formed, and bonding wires BW connecting the sixth bonding pads BP6 on the sixth semiconductor die SD6 to the substrate pads 104 may be formed.

Referring to FIG. 9H, according to an embodiment, the method may include an operation (H), in which, the semiconductor stack SS and the bonding wires BW may be molded on the substrate SB with a molding material 190. In an embodiment, the process of molding with the molding material 190 may include a compression molding or transfer molding process. In an embodiment, the molding material 190 may include an epoxy molding compound EMC. Next, an external connection structure CS may be formed on a lower surface of the substrate SB. For example, conductive pads 102 may be formed on the lower surface of the substrate SB. In an embodiment, the conductive pad 102 may include, but is not limited to, at least one of copper, nickel, zinc, gold, silver, platinum, palladium, chromium, titanium, and alloys thereof. In an embodiment, the conductive pad 102 may be formed by performing a sputtering process or by performing an electrolytic plating process after forming a seed metal layer. After the conductive pads 102 are formed, solder 103 may be formed on each of the conductive pads 102. In an embodiment, the solder 103 may include, but is not limited to, at least one of tin, silver, lead, nickel, copper, and alloys thereof.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor package comprising:
a substrate;
a plurality of semiconductor dies stacked on the substrate, the plurality of semiconductor dies comprising N number of semiconductor dies, wherein N is a natural number greater than or equal to 4; and
a plurality of bonding wires, each of the plurality of bonding wires configured to electrically connect one of the plurality of semiconductor dies to the substrate,
wherein the plurality of semiconductor dies comprises:
a first semiconductor die provided on the substrate;
a second semiconductor die provided on the first semiconductor die with an offset in a first horizontal direction with respect to the first semiconductor die;
an nth semiconductor die provided with an offset in a second horizontal direction opposite to the first horizontal direction with respect to an n-2th semiconductor die, where n is an odd number greater than or equal to 3 and less than or equal to N; and
an mth semiconductor die provided with an offset in the first horizontal direction with respect to an m-2th semiconductor die, where m is an even number equal to or greater than 4 and equal to or less than N.

2. The semiconductor package of claim 1, wherein:
an upper surface of each of the plurality of semiconductor dies comprises:
a first region overlapping a neighboring semiconductor die; and
a second region not overlapping the neighboring semiconductor die,
wherein an area of the second region increases from the first semiconductor die to the Nth semiconductor die.

3. The semiconductor package of claim 1, wherein:
each of the plurality of semiconductor dies comprises a first side, a second side opposite the first side, a third side between the first side and the second side, and a fourth side opposite the third side,
the first side and the second side extend in a third horizontal direction or a fourth horizontal direction which is the opposite direction to the third horizontal direction, and
the third side and the fourth side extend in a fifth horizontal direction intersecting the third horizontal direction or in a sixth horizontal direction opposite to the fifth horizontal direction.

4. The semiconductor package of claim 3, wherein:
the first horizontal direction is the same as the fifth horizontal direction.

5. The semiconductor package of claim 4, wherein:
the substrate comprises a plurality of substrate pad arrays next to the first side of the first semiconductor die and next to the second side of the first semiconductor die.

6. The semiconductor package of claim 5, wherein:
the plurality substrate pad arrays comprises:
a first substrate pad array arranged in a row along the first side of the first semiconductor die;
a second substrate pad array arranged in a row along the second side of the second semiconductor die;
an nth substrate pad array arranged in a row along the first side of the nth semiconductor die; and
an mth substrate pad array arranged in a row along the second side of the mth semiconductor die.

7. The semiconductor package of claim 5, wherein:
neighboring substrate pad arrays among the plurality of substrate pad arrays are spaced apart from each other by a first pitch, and
the first pitch has a range of about 100 μm to about 200 μm.

8. The semiconductor package of claim 4, wherein:
each of the plurality of semiconductor dies comprises a bonding pad array arranged in a row on an area of an upper surface of the respective semiconductor die not overlapped by a neighboring semiconductor die.

9. The semiconductor package of claim 3, wherein:
the first horizontal direction is a direction between the third horizontal direction and the fifth horizontal direction.

10. The semiconductor package of claim 9, wherein:
the substrate comprises a plurality of substrate pad arrays around the first semiconductor die.

11. The semiconductor package of claim 10, wherein:
the plural substrate pad arrays comprises:
a first substrate pad array arranged in a row along the first side of the first semiconductor die and along the third side of the first semiconductor die;
a second substrate pad array arranged in a row along the second side of the second semiconductor die and along the fourth side of the second semiconductor die;
an nth substrate pad array arranged in a row along the first side of the nth semiconductor die and along the third side of the nth semiconductor die; and
an mth substrate pad array arranged in a row along the second side of the mth semiconductor die and along the fourth side of the mth semiconductor die.

12. The semiconductor package of claim 9, wherein:
each of the plurality of semiconductor dies comprises a bonding pad array arranged in a row on an area of an upper surface of the respective semiconductor die not overlapped by a neighboring semiconductor die.

13. A semiconductor package comprising:
a substrate;
a first semiconductor die on the substrate;
a second semiconductor die on the first semiconductor die, the second semiconductor die arranged with an offset in a first horizontal direction with respect to the first semiconductor die;
a third semiconductor die on the second semiconductor die, the third semiconductor die arranged with an offset in a second horizontal direction opposite to the first horizontal direction with respect to the first semiconductor die;
a fourth semiconductor die on the third semiconductor die, the fourth semiconductor die arranged with an offset in the first horizontal direction with respect to the second semiconductor die; and
a plurality of bonding wires configured to electrically connect each of the first semiconductor die, the second semiconductor die, the third semiconductor die, and the fourth semiconductor die to the substrate.

14. The semiconductor package of claim 13, wherein:
the substrate comprises a plurality of substrate pads,
each of the first semiconductor die, the second semiconductor die, the third semiconductor die, and the fourth semiconductor die comprises a plurality of bonding pads, and
each of the plurality of bonding wires electrically configured to connect a corresponding substrate pad among the plurality of substrate pads to a corresponding bonding pad among the plurality of bonding pads.

15. The semiconductor package of claim 14, wherein:
the substrate further comprises a substrate base, and
the plurality of substrate pads protrude from the substrate base.

16. The semiconductor package of claim 14, wherein:
the substrate further comprises a substrate base, and
at least a portion of the plurality of substrate pads are embedded in the substrate base.

17. The semiconductor package of claim 14, wherein:
each of the first semiconductor die, the second semiconductor die, the third semiconductor die, and the fourth semiconductor die further comprises a die base, and
the plurality of bonding pads of each of the first semiconductor die, the second semiconductor die, the third semiconductor die, and the fourth semiconductor die protrudes from the die base of a corresponding one of the first semiconductor die, the second semiconductor die, the third semiconductor die, and the fourth semiconductor die.

18. The semiconductor package of claim 14, wherein:
each of the first semiconductor die, the second semiconductor die, the third semiconductor die, and the fourth semiconductor die further comprises a die base, and
side surfaces and lower surfaces of the plurality of bonding pads of each of the first semiconductor die, the second semiconductor die, the third semiconductor die, and the fourth semiconductor die are embedded in the die base of a corresponding one of the first semiconductor die, the second semiconductor die, the third semiconductor die, and the fourth semiconductor die.

19. A semiconductor package comprising:
a substrate;
a plurality of semiconductor dies stacked on the substrate, the plurality of semiconductor dies comprising N number of semiconductor dies, wherein N is a natural number greater than or equal to 4, and each of the plurality of semiconductor dies comprises a first side and a second side opposite to the first side; and
a plurality of bonding wires, each of the plurality of bonding wires configured to electrically connect one of the plurality of semiconductor dies to the substrate,
wherein the plurality of semiconductor dies comprises:
a first semiconductor die provided on the substrate;
a second semiconductor die provided on the first semiconductor die such that the first side of the second semiconductor die is recessed based on the first side of the first semiconductor die and the second side of the second semiconductor die protrudes based on the second side of the first semiconductor die,
an nth semiconductor die provided such that the first side of the nth semiconductor die protrudes by a first width based on the first side of an n-2th semiconductor die, and the second side of the nth semiconductor die is recessed by the first width based on the second side of the n-2th semiconductor die, wherein n is an odd number equal to or greater than 3 and equal to or less than N, and
an mth semiconductor die of the first semiconductor die to the Nth semiconductor die is provided such that the first side of an mth semiconductor die is recessed by a second width based on the first side of the m-2th semiconductor die and the second side of the mth semiconductor die protrudes by the second width based on the second side of the m-2th semiconductor die, and m is an even number equal to or greater than 4 and equal to or less than N.

20. The semiconductor package of claim 19, wherein:
the first width and the second width have a range of about 50 μm to about 100 μm.
